(19) United States
(12) Patent Application Publication
(10) Pub. No.: US 2025/0079732 A1
(43) Pub. Date: Mar. 6, 2025

(54) ELECTRONIC DEVICE AND CABLE

(71) Applicant: NIDEC CORPORATION, Kyoto (JP)

(72) Inventors: Yukinobu SHIRAISHI, Kyoto (JP); Yoichi SAKAMOTO, Kyoto (JP); Hiroshi MIYAMOTO, Kyoto (JP); Norifumi YUSA, Kyoto (JP); Takashi UCHINO, Kyoto (JP)

(21) Appl. No.: 18/813,248

(22) Filed: Aug. 23, 2024

(30) Foreign Application Priority Data
Aug. 29, 2023 (JP) 2023-138939
Mar. 29, 2024 (JP) 2024-056715

(51) Int. Cl. H01R 12/62; H01B 7/08; H01B 7/17

(52) U.S. Cl. CPC H01R 12/62; H01B 7/0823; H01B 7/17

(57) ABSTRACT

In an electronic device, one end of a cable is on one side end surface in a third direction of a substrate extending in first and second directions. The cable includes a conductive wire, an insulating portion, and an opening portion. The conductive wire extends in the first direction. The opening portion is on the other end surface in the third direction of the insulating portion and opens at least to the other side in the third direction. One side end portion in the first direction of the conductive wire is drawn from the insulating portion to one side in the first direction, and is connected to the one side end surface in the third direction of the substrate. At least a portion of an adhesive on the one side end surface in the third direction of the substrate is in the opening portion.

### CROSS-REFERENCE TO RELATED APPLICATIONS

The present application claims priority under 35 U.S.C. § 119 to Japanese Patent Application No. 2023-138939, filed on Aug. 29, 2023, and Japanese Patent Application No. 2024-056715, filed on Mar. 29, 2024, the entire contents of each of which are hereby incorporated herein by reference.

### 1. FIELD OF THE INVENTION

The present disclosure relates to electronic devices and cables.

### 2. BACKGROUND

An electronic device such as a motor having a structure in which a conductive wire drawn from a cable is connected to a substrate is known.

A full-flat cable is soldered to a conventional motor substrate, but there is a concern that a disconnection may occur at a soldered part due to misalignment, twisting, and the like of the full-flat cable. As a countermeasure, for example, it is conceivable to fix the full-flat cable to the motor substrate with an adhesive, but there is a case where sufficient adhesive strength cannot be obtained because the adhesive is repelled on the surface of the full-flat cable. Therefore, there is a possibility that the fixed lifetime of the cable with respect to the substrate is shortened.

### SUMMARY

An example embodiment of an electronic device according to the present disclosure includes a substrate and a cable. The substrate extends in a first direction and a second direction intersecting the first direction. One end of the cable is located on one side end surface of the substrate in a third direction perpendicular to the first direction and the second direction. The cable includes a conductive wire, an insulating portion, and an opening portion. The conductive wire extends in the first direction at one end of the cable. The insulating portion covers the conductive wire. The opening portion is located on the other end surface in the third direction of the insulating portion and opening at least to the other side in the third direction. One side end portion in the first direction of the conductive wire is a conductive wire end portion drawn from the insulating portion to one side in the first direction, and is connected to one side end surface in the third direction of the substrate. At least a portion of an adhesive located on the one side end surface in the third direction of the substrate is located in the opening portion.

An example embodiment of an electronic device according to the present disclosure includes the substrate and the cable. The substrate extends in the first direction and the second direction intersecting the first direction. One end of the cable is located on one side end surface of the substrate in the third direction perpendicular to the first direction and the second direction. The cable includes the conductive wire, the insulating portion, and a bottom plate portion. The conductive wire extends in the first direction at one end of the cable. The insulating portion covers the conductive wire. The bottom plate portion protrudes to one side in the first direction from one side end portion in the first direction of the insulating portion at one end of the cable and extends in the second direction. One side end portion in the first direction of the conductive wire is a conductive wire end portion drawn from the insulating portion to one side in the first direction, and is connected to one side end surface in the third direction of the substrate.

One end of an example embodiment of a cable according to the present disclosure is located on one side end surface in the third direction of the substrate. The substrate extends in the first direction and the second direction intersecting the first direction. The third direction is perpendicular to the first direction and the second direction. The cable includes the conductive wire, the insulating portion, and the opening portion. The conductive wire extends in the first direction at one end of the cable. The insulating portion covers the conductive wire. The opening portion is located on the other end surface in the third direction of the insulating portion and opening at least to the other side in the third direction. One side end portion in the first direction of the conductive wire is a conductive wire end portion drawn from the insulating portion to one side in the first direction, and is connected to one side end surface in the third direction of the substrate. At least a portion of the adhesive located on the one side end surface in the third direction of the substrate is located in the opening portion.

One end of an example embodiment of a cable according to the present disclosure is located on one side end surface in the third direction of the substrate. The substrate extends in the first direction and the second direction intersecting the first direction. The third direction is perpendicular to the first direction and the second direction. The cable includes the conductive wire, the insulating portion, and the bottom plate portion. The conductive wire extends in the first direction at one end of the cable. The insulating portion covers the conductive wire. The bottom plate portion protrudes to one side in the first direction from one side end portion in the first direction of the insulating portion at one end of the cable and extends in the second direction. One side end portion in the first direction of the conductive wire is a conductive wire end portion drawn from the insulating portion to one side in the first direction, and is connected to one side end surface in the third direction of the substrate.

Further features and advantages of the present disclosure will be further clarified by the following example embodiments.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic view showing a structure in which a conductive wire drawn from a cable is connected to a substrate in an electronic device according to an example embodiment of the present disclosure.

FIG. 2 is a cross-sectional view taken along a dash-dot line II-II of FIG. 1.

FIG. 3A is a schematic view showing a structure example in which a conductive wire drawn from a cable is connected to a substrate in an electronic device according to a first modification of an example embodiment of the present disclosure.

FIG. 3B is a schematic view showing another structure example in which the conductive wire drawn from the cable is connected to the substrate in the electronic device according to the first modification of an example embodiment of the present disclosure.

FIG. 4 is a schematic view showing a structure example in which a conductive wire drawn from a cable is connected to a substrate in an electronic device according to a second modification of an example embodiment of the present disclosure.

FIG. 5 is a schematic view showing a structure example in which a conductive wire drawn from a cable is connected to a substrate in an electronic device according to a third modification of an example embodiment of the present disclosure.

### DETAILED DESCRIPTION

Hereinafter, example embodiments of the present disclosure will be described with reference to the drawings. In the drawings, the identical or corresponding portions are given identical reference signs, and the description thereof is not necessarily repeated.

In the description of example embodiments, for easy understanding, a first direction D1, a second direction D2, and a third direction D3 intersecting one another are appropriately used. In the first direction D1, one orientation is called a “first direction one side D1a”, and the other orientation is called a “first direction other side D1b”. One orientation of the second direction D2 is called a “second direction one side D2a”, and the other orientation is called a “second direction other side D2b”. One orientation of the third direction D3 is called a “third direction one side D3a”, and the other orientation is called a “third direction other side D3b”.

In a positional relationship between any of an azimuth, a line, and a plane and any other, “parallel” includes not only a state in which both of them do not intersect at all no matter how long they extend, but also a state in which they are substantially parallel. In addition, “perpendicular” and “orthogonal” include not only a state in which both of them intersect each other at 90 degrees, but also a state in which they are substantially perpendicular and a state in which they are substantially orthogonal. That is, “parallel”, “perpendicular”, and “orthogonal” each include a state in which a positional relationship between the two has an angular deviation that does not depart from the gist of the present disclosure.

These are names used merely for description, and are not intended to limit actual positional relationships, directions, names, and the like.

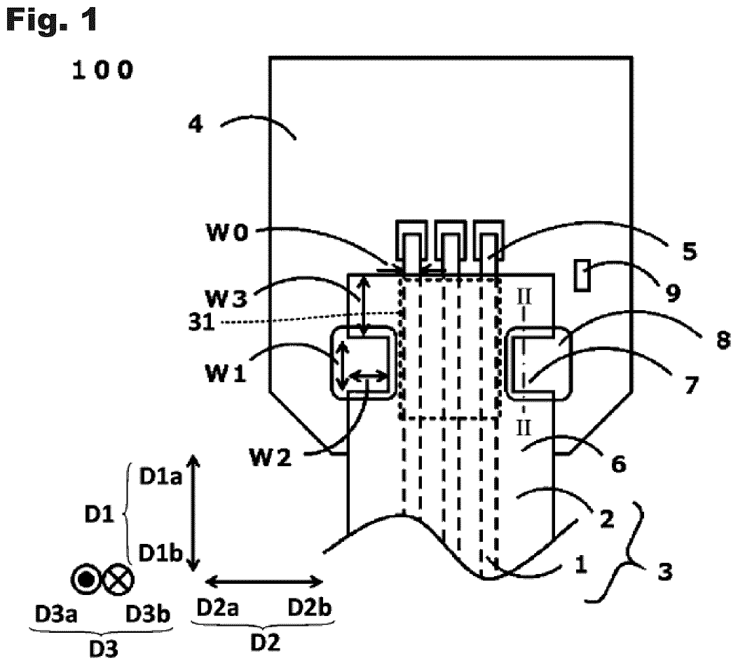

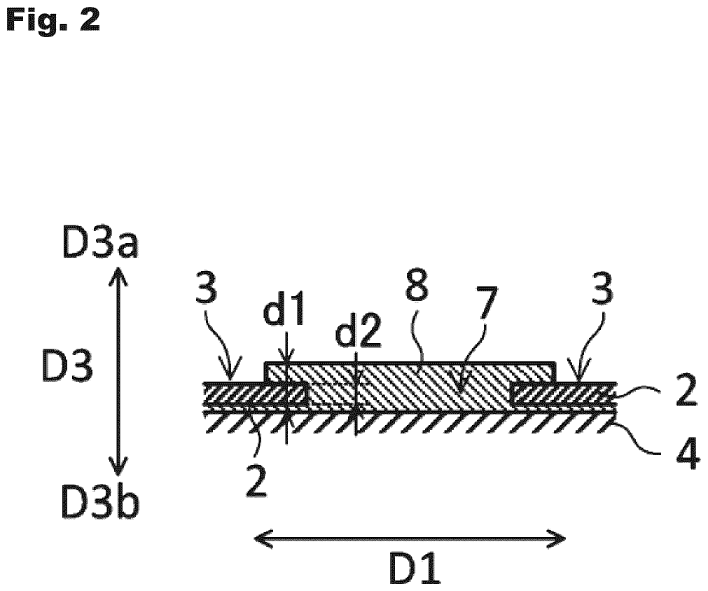

FIG. 1 is a schematic view showing a structure in which a conductive wire 1 drawn from a cable 3 is connected to a substrate 4 in an electronic device 100 according to an example embodiment. FIG. 2 is a cross-sectional view taken along a dash-dot line II-II of FIG. 1.

The electronic device 100 is, for example, a motor or a fan motor. However, this example does not exclude a configuration in which the electronic device 100 is a device other than the motor and the fan motor. The electronic device 100 may be a device having a structure in which the conductive wire 1 drawn from the cable 3 is connected to the substrate 4.

As shown in FIG. 1, the electronic device 100 includes the cable 3 and the substrate 4. The substrate 4 extends in the first direction D1 and the second direction D2. The second direction D2 intersects the first direction D1, and is perpendicular to the first direction D1 in the present example embodiment. One end of the cable 3 is located on an end surface on the third direction one side D3a of the substrate 4. In the present example embodiment, the third direction D3 is perpendicular to the first direction D1 and the second direction D2. In other words, the substrate 4 is located on the third direction other side D3b with respect to the cable 3. The substrate 4 has a thickness in the third direction D3.

The cable 3 includes the conductive wire 1 and an insulating portion 2. The conductive wire 1 extends in the first direction D1 at one end of the cable 3. The insulating portion 2 insulates the conductive wire 1. A plurality of the conductive wires 1 are arranged in the second direction D2 intersecting the first direction D1. That is, the plurality of conductive wires 1 are arranged in parallel. The number of conductive wires 1 is 3 in the present example embodiment, but is not limited to this example. The conductive wire 1 may be single or plural other than 3.

An end portion on the first direction one side D1a of the conductive wire 1 is a conductive wire end portion 5 drawn from the insulating portion 2 to the first direction one side D1a, and is connected to an end surface on the third direction one side D3a of the substrate 4. That is, the cable 3 includes the conductive wire end portion 5.

An end portion of at least in the second direction D2 of the insulating portion 2 is an edge portion 6 that is flat in the third direction D3. For example, the insulating portion 2 has the edge portion 6 at least at a part of each of both end portions in the second direction D2. The edge portion 6 is flat in the third direction D3. Here, the edge portion 6 being flat in the third direction D3 means that the width in the third direction D3 of the edge portion 6 is equal to or less than the width in the first direction D1 of the edge portion 6, and the width in the third direction D3 of the edge portion 6 is equal to or less than the width in the second direction D2 of the edge portion 6.

Here, in the present example embodiment, the conductive wire 1 is a rectangular conductor. The insulating portion 2 is two insulating tapes arranged in parallel to face each other in the third direction D3, and is, for example, a PVC resin tape. Between the two insulating tapes, a plurality of rectangular conductors (conductive wire 1) are arranged in parallel at regular intervals in the second direction D2. Both end portions of the rectangular conductor (conductive wire 1) are exposed from the end portions of the two insulating tapes (insulating portions 2) over a certain length to form a connection terminal part. The two insulating tapes are integrated by fusion. The edge portion 6 may be positioned on both sides in the second direction D2 with respect to the conductive wire 1, and is not necessarily positioned at an outer edge portion of the insulating portion 2.

Here, the conductive wire end portion 5 is connected by soldering to a land part positioned on the end surface on the third direction one side D3a of the substrate 4. However, the connection means of the conductive wire end portion 5 with respect to the land part is not limited to soldering. For example, a conductive paste such as a silver paste may be used as an outer connection means.

The cable 3 has an opening portion 7. The opening portion 7 is located on the end surface on the third direction other side D3b of the insulating portion 2 and opens at least on the third direction other side D3b. The opening portion 7 is disposed at the edge portion 6. In the present example embodiment, as shown in FIG. 1, the opening portion 7 is disposed at each of the edge portions 6 at both end portions in the second direction D2, and penetrates (the edge portion 6 of) the insulating portion 2 in the third direction D3. That is, the edge portion 6 has the opening portion 7. In other words, the opening portion 7 is a recess portion recessed inward in the second direction D2 from an outer side end portion in the second direction D2 of (the edge portion 6 of) the insulating portion 2.

The insulating portion 2 of the cable 3 is located on the end surface on the third direction one side D3a of the substrate 4 using an adhesive 8. For example, at least a part of the adhesive 8 located on the end surface on the third direction one side D3a of the substrate 4 is disposed (filled) in the opening portion 7. The adhesive 8 may be, for example, a UV adhesive, an acrylic adhesive, an epoxy adhesive, or a urethane adhesive. Furthermore, the adhesive 8 may be a coating agent exhibiting adhesiveness such as HumiSeal. However, this example does not exclude a configuration in which the adhesive 8 is other than these.

In this way, the adhesive 8 disposed in the opening portion 7 positions the cable 3 with respect to the substrate 4, and misalignment, twisting, and the like of the cable 3 are suppressed. As a result, it is possible to suppress disconnection of the conductive wire end portion 5 due to misalignment and twisting of the cable 3. Therefore, it is possible to improve the fixed lifetime of the cable 3 with respect to the substrate 4.

In a case where the cable 3 is to be fixed to the substrate 4 with the adhesive 8, there is a concern that sufficient adhesive strength cannot be obtained in a case where the surface of the cable 3 and the adhesive 8 are not compatible with each other, for example, the adhesive 8 is repelled on the surface of the cable 3. The edge portion 6 has the opening portion 7, and at least a part of the adhesive 8 located on the end surface on the third direction one side D3a of the substrate 4 is disposed in the opening portion 7, whereby it is possible to position the cable 3 with respect to the substrate 4 and suppress misalignment, twisting, and the like of the cable 3 regardless of compatibility between the surface of the cable 3 and the adhesive 8.

At this time, a part of the adhesive 8 may be located on the end surface on the third direction one side D3a of the insulating portion 2. For example, a part of the adhesive 8 is disposed in the opening portion 7. On the other hand, preferably, another part of the adhesive 8 is located on the third direction one side D3a relative to the end surface on the third direction one side D3a of the insulating portion 2, and covers the end surface on the third direction one side D3a of the insulating portion 2 along at least a part of the outer edge of the opening portion 7 as viewed from the third direction D3.

Furthermore, as shown in FIG. 2, a width d1 in the third direction D3 of the portion covering the end surface on the third direction one side D3a of the insulating portion 2 of the adhesive 8 is equal to or greater than a width d2 of the opening portion 7.

For example, in at least a part of the peripheral edge of the opening portion 7, at least a part of the adhesive 8 is located on the third direction other side D3b of the cable 3. In other words, a part of the adhesive 8 located on the end surface on the third direction one side D3a of the substrate 4 in the opening portion 7 rides on the third direction one side D3a of (the insulating portion 2 of) the cable 3 in at least a part of the peripheral edge of the opening portion 7. At this time, the cable 3 can be more reliably positioned with respect to the substrate 4, and misalignment, twisting, and the like of the cable 3 are reliably suppressed.

However, this example does not exclude a configuration in which a part of the adhesive 8 is not located on the end surface on the third direction one side D3a of the insulating portion 2. In at least a part of the peripheral edge of the opening portion 7, regardless of whether or not at least a part of the adhesive 8 is located on the third direction one side D3a of the cable 3, the cable 3 is positioned with respect to the substrate 4, and misalignment, twisting, and the like of the cable 3 are suppressed. In a case where in at least a part of the peripheral edge of the opening portion 7, at least a part of the adhesive 8 is not located on the third direction other side D3b of the cable 3, when misalignment and twisting of the cable 3 occur, the peripheral edge of the opening portion 7 of the cable 3 hits the adhesive 8 disposed in the opening portion 7, whereby movement of the peripheral edge of the opening portion 7 is restricted. Also in a case where in at least a part of the peripheral edge of the opening portion 7, at least a part of the adhesive 8 is located on the third direction other side D3b of the cable 3, when misalignment and twisting of the cable 3 occur, movement of the peripheral edge of the opening portion 7 of the cable 3 is restricted by the adhesive 8 disposed in the opening portion 7.

In other words, the opening portion 7 provided in the cable 3 plays a role of a recess. On the other hand, the adhesive 8 disposed in the opening portion 7 plays a role of a projection. That is, the projection disposed in the recess restricts the movement of the recess. Thus, it is not easy to provide, on the substrate 4, a projection that is engaged with the recess provided in the cable 3 and restricts the movement of the cable 3. However, by disposing the adhesive 8 on the end surface on the third direction one side D3a of the substrate 4 such that at least a part of the adhesive 8 disposed, for example, by coating on the end surface on the third direction one side D3a of the substrate 4 is disposed in the opening portion 7, the adhesive 8 is cured in accordance with the shape of the opening portion 7, and therefore it is possible to easily provide a projection (i.e., a fitting structure of the projection with respect to the recess) to be engaged with the recess of the opening portion 7.

Preferably, the adhesive 8 is interposed between the cable 3 and the substrate 4 in the third direction D3. For example, as shown in FIG. 2, in at least a part of the outer edge at the end portion on the third direction other side D3b of the opening portion 7, the adhesive 8 is disposed between the end surface on the third direction other side D3b of (the insulating portion 2 of) the cable 3 and the end surface on the third direction one side D3a of the substrate 4. This can improve the engagement strength (i.e., the fitting strength of the projection with respect to the recess) of the projection (the adhesive 8 in the opening portion 7) with the recess (the opening portion 7).

In FIG. 1, the opening portion 7 is positioned at the outer side end in the second direction D2 of the edge portion 6. That is, the opening portion 7 opens at the end portion in the second direction D2 of the edge portion 6. However, the present disclosure is not limited to this example, and the opening portion 7 may be separated inward in the second direction D2 from an outer side end in the second direction D2 of (the edge portion 6 of) the insulating portion 2 as viewed from the third direction D3. In other words, at least any of the opening portions 7 may be disposed between the outer side end in the second direction D2 of (the edge portion 6 of) the insulating portion 2 and the conductive wire 1 with a space therebetween as viewed from the third direction D3.

The opening portion 7 has a hole shape whose peripheral edge is edged by the insulating portion 2, and a single opening portion 7 is disposed at each edge portion 6. The shape of the opening portion 7 is a rectangle in FIG. 1 as viewed from the third direction D3. However, the present disclosure is not limited to this example, and the shape of the opening portion 7 as viewed from the third direction D3 may be other than a rectangle, and may be, for example, an n-sided polygon shape such as a triangle (n is a positive integer of 3 or more), a circle, a semicircle, or the like. At least any of the edge portions 6 may have a plurality of opening portions 7. Furthermore, in at least one of the edge portions 6, at least one of the plurality of opening portions 7 may be positioned at an outer end in the second direction D2 of the edge portion 6. That is, at least one of the plurality of opening portions 7 may be positioned at the outer ends in the second direction D2 of all the opening portions 7 and the edge portions 6. Alternatively, some of the plurality of opening portions 7 may be disposed at the outer end in the second direction D2 of the edge portion 6, and the others may be disposed away inward in the second direction D2 from the outer end in the second direction D2 of the edge portion 6.

Since at least one of the opening portions 7 is positioned at the end in the second direction D2 of the edge portion 6, both ends in the second direction D2 of the cable 3 can be positioned with respect to the substrate 4, and thus, it is possible to more reliably suppress misalignment, twisting, and the like of the cable 3. Furthermore, the work of disposing the adhesive 8 on the end surface on the third direction one side D3a of the substrate 4 around the cable 3 and the work of disposing the adhesive 8 on the end surface on the third direction one side D3a of the substrate 4 in the opening portion 7 can be continuously performed, and therefore the workability of disposing the adhesive 8 can be improved.

At this time, at least a part of the adhesive 8 may be located on the third direction one side D3a of the cable 3 in at least a part of the outer end in the second direction D2 of the insulating portion 2. In other words, a part of the adhesive 8 located on the end surface on the third direction one side D3a of the substrate 4 around the cable 3 rides on the third direction one side D3a of the cable 3 in at least a part of the outer end in the second direction D2 of the insulating portion 2. As a result, the cable 3 can be more reliably positioned with respect to the substrate 4, and misalignment, twisting, and the like of the cable 3 are more reliably suppressed.

Preferably, as viewed from the third direction D3, a width W1 in the first direction D1 of the opening portion 7 is equal to or greater than a width W0 in the second direction D2 of the conductive wire 1. For example, as viewed from the third direction D3, the maximum value of the width W1 of the opening portion 7 is equal to or greater than the minimum value of the width W0 of the conductive wire 1. Preferably, as viewed from the third direction D3, a width W2 in the second direction D2 of the opening portion 7 is equal to or greater than the width W0 in the second direction D2 of the conductive wire 1. For example, as viewed from the third direction D3, the maximum value of the width W2 of the opening portion 7 is equal to or greater than the minimum value of the width W0 of the conductive wire 1. Here, the width W0 in the second direction D2 of the conductive wire 1 is defined at a position where the conductive wire 1 is drawn from the insulating portion 2 to one side in the first direction D1, in other words, the width in the second direction D2 at the end on the other side in the first direction D1 of the conductive wire end portion 5.

In this way, since the opening portion 7 can be enlarged, the adhesive 8 disposed in the opening portion 7 can more reliably position the cable 3 with respect to the substrate 4, and misalignment, twisting, and the like of the cable 3 are more reliably suppressed.

Preferably, a width W3 in the first direction D1 between the end on the first direction other side D1b of the conductive wire end portion 5 and the end on the first direction one side D1a of the opening portion 7 is equal to or greater than the width W0 in the second direction D2 of the conductive wire 1. For example, the minimum value of the width W3 is equal to or greater than the minimum value of the width W0 of the conductive wire 1. This can suppress an electronic component 9 disposed around the conductive wire end portion 5 connected to the substrate 4 from deteriorating the workability of disposing of the adhesive 8.

Preferably, a member other than the adhesive 8 may be used as a fixing means of the insulating portion 2 to the substrate 4. For example, the cable 3 further includes a fixing portion 31. The fixing portion 31 fixes the insulating portion 2 on the end surface on the third direction one side D3a of the substrate 4. For example, the fixing portion 31 is disposed between the insulating portion 2 and the substrate 4. In FIG. 1, the fixing portion 31 is disposed between the opening portions 7 disposed at the edge portions 6 as viewed from the third direction D3, and particularly overlaps the conductive wire 1 as viewed from the third direction D3. The fixing portion 31 is not particularly limited, but for example, a double-sided tape is used. However, the present disclosure is not limited to this example, and the fixing portion 31 may be an adhesive member same as or different from the adhesive 8.

When a force toward at least the third direction one side D3a acts on the cable 3 due to the disposing of the fixing portion 31, the fixing portion 31 makes it difficult for the insulating portion 2 to separate from the substrate 4. Therefore, since the conductive wire 1 (in particular, the conductive wire end portion 5) becomes hardly bent, the fixed lifetime of the cable 3 with respect to the substrate 4 can be improved.

However, this example does not exclude a configuration in which the fixing portion 31 is not disposed between the opening portions 7, and does not exclude a configuration in which the fixing portion 31 does not overlap the conductive wire 1 as viewed from the third direction D3. The above-described example does not exclude a configuration in which the cable 3 in which the cable 3 is disposed at each edge portion 6 does not include the fixing portion 31.

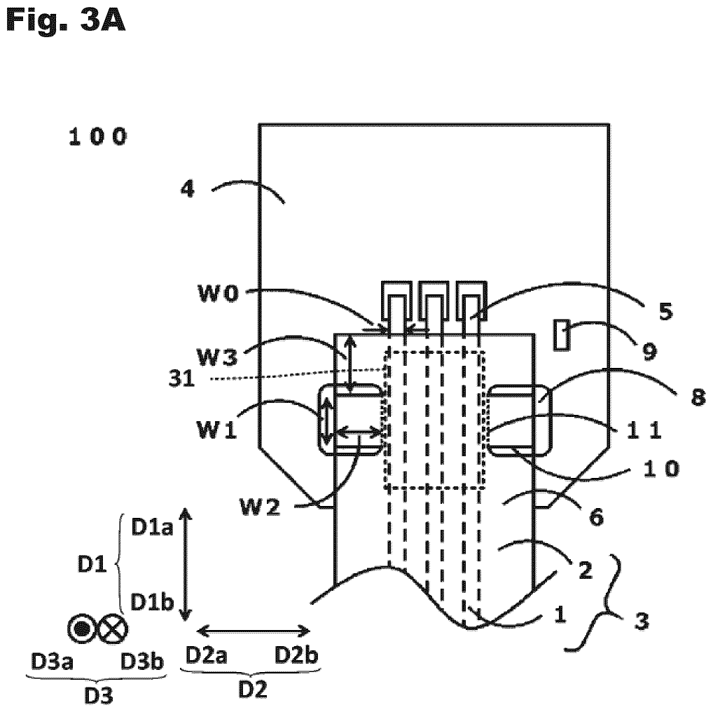

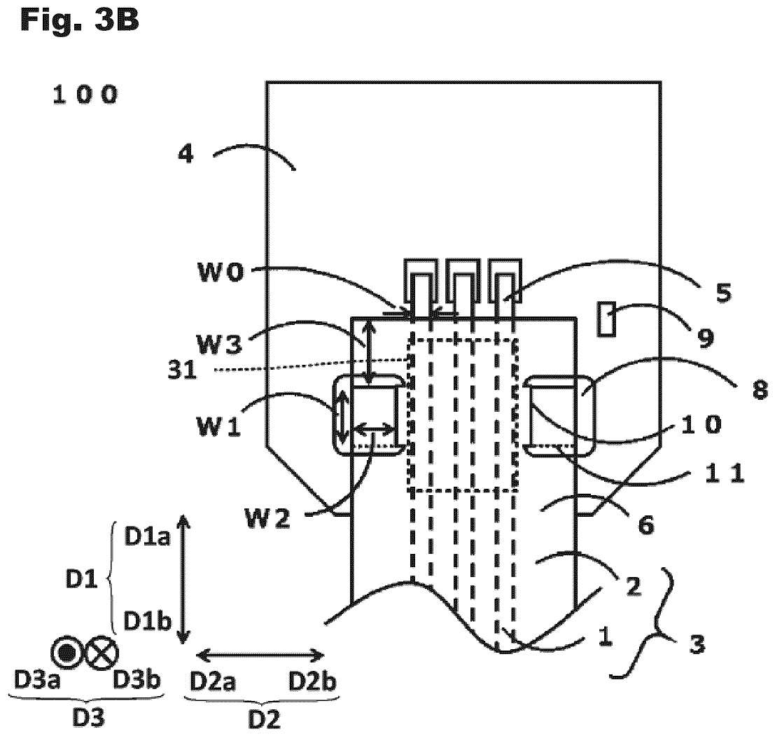

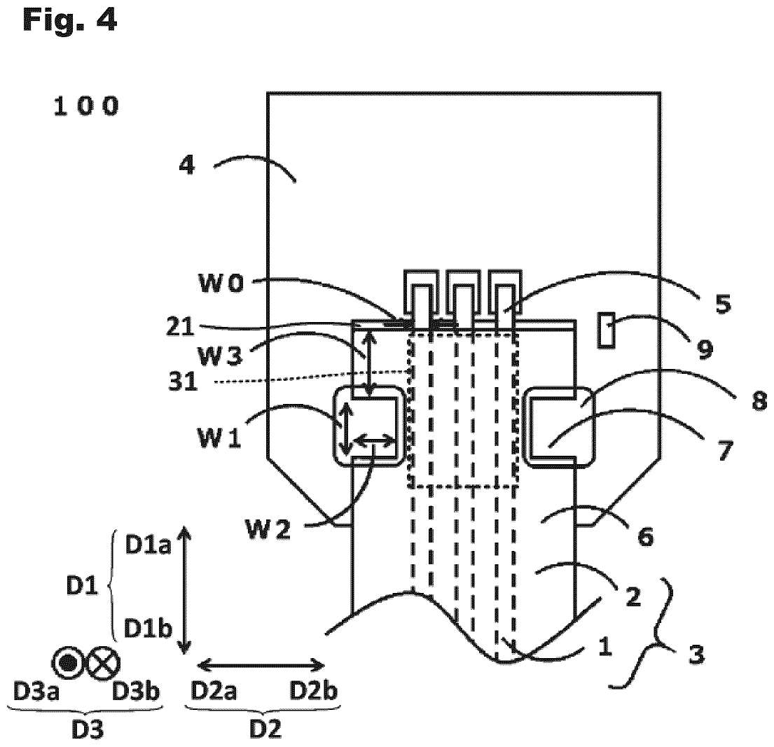

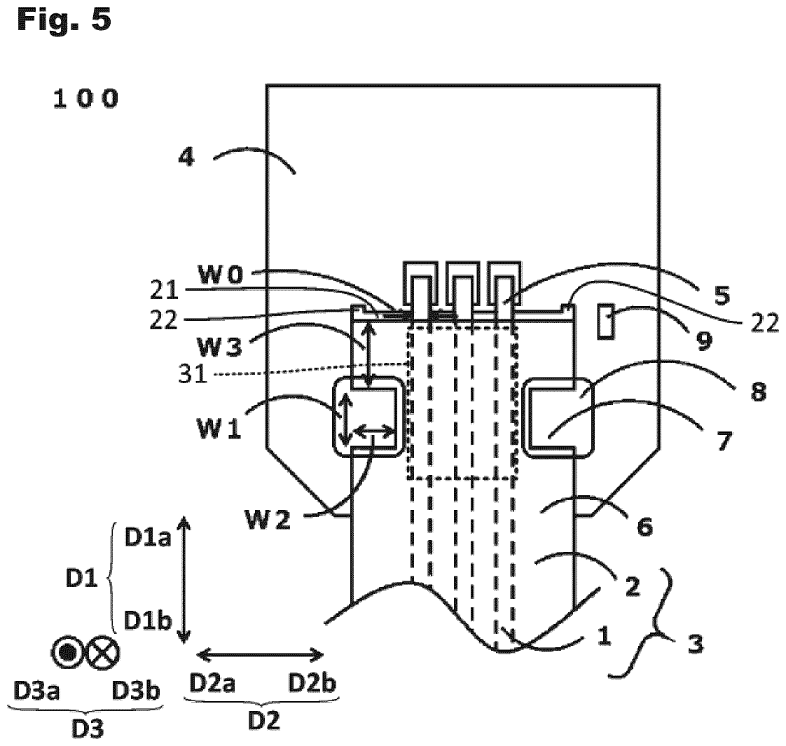

Next, the first modification to a third modification of the example embodiment will be described with reference to FIGS. 3A to 5. FIG. 3A is a schematic view showing a structure example in which the conductive wire 1 drawn from the cable 3 is connected to the substrate 4 in the electronic device 100 according to the first modification. FIG. 3B is a schematic view showing another structure example in which the conductive wire 1 drawn from the cable 3 is connected to the substrate 4 in the electronic device 100 according to the first modification. FIG. 4 is a schematic view showing a structure example in which the conductive wire 1 drawn from the cable 3 is connected to the substrate 4 in the electronic device 100 according to the second modification. FIG. 5 is a schematic view showing a structure example in which the conductive wire 1 drawn from the cable 3 is connected to the substrate 4 in the electronic device 100 according to the third modification. In each of the modifications, a configuration different from that of the example embodiment and other modifications will be described. In each of the modifications, the same reference signs are given to similar constituent elements to those in the example embodiment and other modifications, and the description thereof may be omitted. The example embodiment and the first to third modifications thereof can be implemented in any combination as long as there is no particular contradiction.

In the above-described example embodiment, the opening portion 7 is provided as a through hole penetrating the edge portion 6 in the third direction D3, but in the first modification shown in FIGS. 3A and 3B, a part of the edge portion 6 is provided with a cut 10, and a part of the edge portion 6 is disposed in a direction away from the substrate 4 by being bent with a fold 11. Then, in the above-described example embodiment, at least a part of the adhesive 8 is disposed inside the opening portion 7, but in the first modification shown in FIGS. 3A and 3B, at least a part of the adhesive 8 is disposed between a part where the part of the edge portion 6 is disposed in the direction away from the substrate 4 and the substrate 4 by the cuts 10 and the fold 11. In other words, the opening portion 7 may be formed by a through hole as in the example embodiment, or may be formed by the cut 10 and the fold 11 as in the first modification. At this time, since the part where the part of the edge portion 6 is disposed in the direction away from the substrate 4 covers at least a part of the adhesive 8 disposed between the edge portion 6 and the substrate 4, it is possible to suppress the adhesive 8 from peeling off from the substrate 4.

Here, as shown in FIG. 3A, two cuts 10 extending in the second direction D2 may be provided, and a part between the cuts 10 may be bent in the second direction D2, and as shown in FIG. 3B, the cut 10 extending in the first direction D1 and the cut 10 extending in the second direction D2 may be provided, and a part edged by the cut 10 may be bent in the first direction D1. The cut 10 and the fold 11 are not limited to the examples of FIGS. 3A and 3B.

In the second modification, as shown in FIG. 4, the cable 3 further includes a bottom plate portion 21. The bottom plate portion 21 protrudes in the one first direction D1a from the end portion on the first direction one side D1a of the insulating portion 2 at one end of the cable 3, and extends in the second direction D2. The width in the third direction D3 of the bottom plate portion 21 is smaller than the width in the third direction D3 of the insulating portion 2. Therefore, the bottom plate portion 21 has a flexibility higher than that of the insulating portion 2.

The width in the second direction D2 of the bottom plate portion 21 is the same as the width in the second direction D2 of the insulating portion 2 in FIG. 4. However, the present disclosure is not limited to this example, and the width in the second direction D2 of the bottom plate portion 21 may be smaller or larger than the width in the second direction D2 of the insulating portion 2 in FIG. 4.

This can increase the number of locations where the conductive wire end portion 5 is easily bent as compared with a configuration in which the cable 3 does not have the bottom plate portion 21 when a force toward at least the third direction one side D3a acts on the cable 3.

For example, in a configuration in which the cable 3 does not have the bottom plate portion 21, with respect to the substrate 4, the conductive wire end portion 5 is likely to be greatly bent at the position in the first direction D1 same as the end portion on the first direction one side D1a of the insulating portion 2. On the other hand, in the above-described configuration, with respect to the substrate 4, the conductive wire end portion 5 is easily bent at least at two locations including the position in the first direction D1 same as the end portion on the first direction one side D1a of the bottom plate portion 21 and the position in the first direction D1 same as the end portion on the first direction one side D1a of the insulating portion 2. Therefore, the degree of bending at each location easily bent can be reduced. Therefore, it is possible to suppress the possibility that strength deterioration, fracture, or the like due to bending occurs in the conductive wire 1 (in particular, the conductive wire end portion 5), and thus, it is possible to improve the fixed lifetime of the cable 3 with respect to the substrate 4.

In FIG. 4, at least a part of the end surface on the third direction other side D3b of the bottom plate portion 21 comes into contact with the end surface on the third direction one side D3a of the substrate 4. For example, in FIG. 4, the bottom plate portion 21 protrudes from the end portion on the third direction other side D3b of the insulating portion 2. This enables the part on the first direction other side D1b of the end surface on the third direction other side D3b of the bottom plate portion 21 to be easily brought into contact with the end surface on the third direction one side D3a of the substrate 4. Therefore, the contact area between the bottom plate portion 21 and the substrate 4 can be increased, and the bottom plate portion 21 can be bent in a wider range in the first direction D1. Therefore, even if the above-described force acts on the cable 3, the degree of bending at the bottom plate portion 21 can be further reduced.

However, the present disclosure is not limited to the above example, and at least a part of the end surface on the third direction other side D3b of the bottom plate portion 21 need not be in contact with the end surface on the third direction one side D3a of the substrate 4, and may be adhered to the end surface of the substrate 4 with an adhesive member or the like, for example. The above-described example does not exclude a configuration in which the bottom plate portion 21 does not protrude from the part on the third direction other side D3b of the insulating portion 2 at the end portion on the first direction one side D1a of the insulating portion 2. For example, at the end portion on the first direction one side D1a of the insulating portion 2, the bottom plate portion 21 may protrude from a part on the third direction one side D3a of the insulating portion 2 side, or may protrude from a part between both end portions in the third direction D3 of the insulating portion 2. Even in these cases, the fixed lifetime of the cable 3 with respect to the substrate 4 can be improved similarly to FIG. 4.

In FIG. 4, the bottom plate portion 21 is disposed between the conductive wire 1 (in particular, the conductive wire end portion 5) and the substrate 4 in the third direction D3. That is, the bottom plate portion 21 is disposed between the part on the first direction other side D1b of the conductive wire end portion 5 and (the end surface on the third direction one side D3a of) the substrate 4. However, the present disclosure is not limited to this example, and the bottom plate portion 21 need not be disposed between the conductive wire 1 and the substrate 4 in the third direction D3, and for example, may be located on the third direction one side D3a relative to at least one conductive wire 1 (in particular, the conductive wire end portion 5). Even in this case, the fixed lifetime of the cable 3 with respect to the substrate 4 can be improved similarly to FIG. 4.

In the third modification, as shown in FIG. 5, the cable 3 further includes a protrusion plate portion 22. The protrusion plate portion 22 protrudes on the first direction one side D1a from the end portion in the first direction D1 of the insulating portion 2 at one end of the cable 3. In FIG. 5, a pair of the protrusion plate portions 22 respectively protrude from both end portions in the second direction D2 of the insulating portion 2 as viewed in the third direction D3. However, the present disclosure is not limited to this example, and the protrusion plate portion 22 may protrude from only any of the end portion on the second direction one side D2a and the end portion on the second direction other side D2b of the insulating portion 2.

The position of the end portion on the first direction one side D1a of the protrusion plate portion 22 is on the first direction other side D1b relative to the end portion on the first direction one side D1a of the conductive wire end portion 5, and is preferably different from the end portion on the first direction one side D1a of the bottom plate portion 21 in the first direction D1. More preferably, the position of the end portion on the first direction one side D1a of at least one protrusion plate portion 22 is on the first direction one side D1a relative to the end portion on the first direction one side D1a of the bottom plate portion 21. However, the present disclosure is not limited to this example, and the position of the end portion on the first direction one side D1a of at least one protrusion plate portion 22 may be on the first direction other side D1b relative to the end portion on the first direction one side D1a of the bottom plate portion 21.

This can further increase the number of locations where the conductive wire end portion 5 of the cable 3 is easily bent. For example, with respect to the substrate 4, the conductive wire end portion 5 is easily bent at least at three locations including a position in the first direction D1 same as the end portion on the first direction one side D1a of the bottom plate portion 21, a position in the first direction D1 same as the end portion on the first direction one side D1a of the protrusion plate portion 22, and a position in the first direction D1 same as the end portion on the first direction one side D1a of the insulating portion 2. Therefore, the degree of bending at each location easily bent can be further reduced. Therefore, the fixed lifetime of the cable 3 with respect to the substrate 4 can be further improved.

For example, the protrusion plate portion 22 protrudes from the end portion on the third direction other side D3b of the insulating portion 2. This enables the part on the first direction other side D1b of the end surface on the third direction other side D3b of the protrusion plate portion 22 to be easily brought into contact with the end surface on the third direction one side D3a of the substrate 4. Therefore, the contact area between the protrusion plate portion 22 and the substrate 4 can be increased, and the protrusion plate portion 22 can be bent in a wider range in the first direction D1. Therefore, even if the above-described force acts on the cable 3, the degree of bending at the protrusion plate portion 22 can be further reduced.

However, this example does not exclude a configuration in which the at least one protrusion plate portion 22 does not protrude from the end portion on the third direction other side D3b of the insulating portion 2. For example, at the end portion on the first direction one side D1a of the insulating portion 2, the protrusion plate portion 22 may protrude from a part on the third direction one side D3a of the insulating portion 2 side, or may protrude from a part between both end portions in the third direction D3 of the insulating portion 2. Even in these cases, the fixed lifetime of the cable 3 with respect to the substrate 4 can be further improved similarly.

As described above, in FIG. 5, the cable 3 has the bottom plate portion 21. The at least one protrusion plate portion 22 may be integrated with the bottom plate portion 21, and may be further continuous to the bottom plate portion 21 in the second direction D2. Alternatively, the at least one protrusion plate portion 22 need not be integrated with the bottom plate portion 21, and need not be continuous to the bottom plate portion 21 in the second direction D2.

However, this example does not exclude a configuration in which the cable 3 does not have the bottom plate portion 21. For example, even if the bottom plate portion 21 is omitted in the third modification, the conductive wire end portion 5 is easily bent at at least two locations similarly to the second modification by the protrusion plate portion 22. Therefore, it is possible to obtain the improvement effect of the fixed lifetime of the cable 3 with respect to the substrate 4.

The example embodiment of the present disclosure is described above with reference to the drawings. However, the above example embodiment is merely an example of the present disclosure, and the present disclosure is not limited to the above example embodiment, and can be implemented in various aspects without departing from the gist of the present disclosure. For easy understanding, the drawings schematically mainly show respective constituent elements, and the thickness, length, number, and the like of each illustrated constituent element may be different from the actual thickness, length, number, and the like for convenience of creation of the drawings. The material, shape, dimensions, and the like of the constituent elements described in the above example embodiment are merely examples and are not particularly limited, and various modifications can be made without substantially departing from the effects of the present disclosure. The configuration of the example embodiment may be appropriately modified without departing from the technical idea of the present disclosure. Example embodiments may also be implemented in combination as far as possible.

Hereinafter, the example embodiment described so far will be collectively described.

For example, an electronic device of the present disclosure has a configuration (first configuration) including a substrate extending in a first direction and a second direction intersecting the first direction, and a cable including one end located on one side end surface in a third direction perpendicular to the first direction and the second direction of the substrate, wherein the cable includes a conductive wire extending in the first direction at one end of the cable, an insulating portion covering the conductive wire, and an opening portion located on another end surface in the third direction of the insulating portion and opening at least to the other side in the third direction, one side end portion in the first direction of the conductive wire is a conductive wire end portion drawn from the insulating portion to one side in the first direction, and is connected to one side end surface in the third direction of the substrate, and at least a portion of an adhesive located on the one side end surface in the third direction of the substrate is located in the opening portion.

Alternatively, an electronic device of the present disclosure has a configuration (second configuration) including a substrate extending in a first direction and a second direction intersecting the first direction, and a cable including one end located on one side end surface in a third direction perpendicular to the first direction and the second direction of the substrate, wherein the cable includes a conductive wire extending in the first direction at one end of the cable, an insulating portion covering the conductive wire, and a bottom plate portion protruding to one side in the first direction from one side end portion in the first direction of the insulating portion at one end of the cable and stretching in the second direction, and one side end portion in the first direction of the conductive wire is a conductive wire end portion drawn from the insulating portion to one side in the first direction, and is connected to one side end surface in the third direction of the substrate.

The electronic device having the second configuration may have a configuration (third configuration) in which the cable further includes a protrusion plate portion protruding from an end portion in the first direction of the insulating portion to one side in the first direction at one end of the cable, and a position of one side end portion in the first direction of the protrusion plate portion is on another side in the first direction relative to one side end portion in the first direction of the conductive wire end portion, and is different from one side end portion in the first direction of the bottom plate portion in the first direction.

The electronic device having the second or third configuration may have a configuration (fourth configuration) in which the cable further includes an opening portion located on another end surface in the third direction of the insulating portion and opening at least to the other side in the third direction, and at least a portion of an adhesive located on one side end surface in the third direction of the substrate is located in the opening portion.

The electronic device having the first or fourth configuration may have a configuration (fifth configuration) in which the opening portion penetrates the insulating portion in the third direction, a portion of the adhesive is located in the opening portion, and another portion of the adhesive is located on one side in the third direction relative to one side end surface in the third direction of the insulating portion, and covers the one side end surface in the third direction of the insulating portion along at least a portion of an outer edge of the opening portion as viewed from the third direction.

The electronic device having the fifth configuration may have a configuration (sixth configuration) in which a width in the third direction of a portion covering the one side end surface in the third direction of the insulating portion of the adhesive is equal to or greater than a width in the third direction of the opening portion.

The electronic device having any of the first and fourth to sixth configurations may have a configuration (seventh configuration) in which the adhesive is located between another side end surface in the third direction of the cable and one side end surface in the third direction of the substrate in at least a portion of an outer edge in another side end portion in the third direction of the opening portion.

The electronic device having any of the first and fourth to seventh configurations may have a configuration (eighth configuration) in which an end portion of at least in the second direction of the insulating portion is an edge portion flat in the third direction, and the opening portion is located at the edge portion.

The electronic device having any of the first and fourth to seventh configurations may have a configuration (ninth configuration) in which the opening portion opens at an end portion in the second direction of the edge portion.

The electronic device having any of the first and fourth to eighth configurations may have a configuration (tenth configuration) in which a width in the first direction of the opening portion is equal to or greater than a width in the second direction of the conductive wire.

The electronic device having any of the first and fourth to ninth configurations may have a configuration (eleventh configuration) in which a width in the second direction of the opening portion is equal to or greater than a width in the second direction of the conductive wire.

The electronic device having any of the first and fourth to tenth configurations may have a configuration (twelfth configuration) in which an interval in the first direction between another side end in the first direction of the conductive wire end portion and the opening portion is equal to or greater than a width in the second direction of the conductive wire.

The electronic device having any of the first and fourth to eleventh configurations may have a configuration (thirteenth configuration) of further including: a fixing portion to fix the cable onto one side end surface in the third direction of the substrate, wherein the fixing portion is located between the insulating portion and the substrate.

A cable of the present disclosure is a cable having one end located on one side end surface of a substrate extending in a first direction and a second direction intersecting the first direction, the one side end surface of the substrate in a third direction perpendicular to the first direction and the second direction, the cable having a configuration (fourteenth configuration) including a conductive wire extending in the first direction at one end of the cable, an insulating portion insulating the conductive wire, and an opening portion located on another end surface in the third direction of the insulating portion and opening at least to the other side in the third direction, wherein one side end portion in the first direction of the conductive wire is a conductive wire end portion drawn from the insulating portion to one side in the first direction, and is connected to one side end surface in the third direction of the substrate, and at least a portion of an adhesive located on the one side end surface in the third direction of the substrate is located in the opening portion.

Alternatively, a cable of the present disclosure is a cable having one end located on one side end surface of a substrate extending in a first direction and a second direction intersecting the first direction, the one side end surface of the substrate in a third direction perpendicular to the first direction and the second direction, the cable having a configuration (fifteenth configuration) including a conductive wire extending in the first direction at one end of the cable, an insulating portion covering the conductive wire, and a bottom plate portion protruding to one side in the first direction from one side end portion in the first direction of the insulating portion at one end of the cable and stretching in the second direction, wherein one side end portion in the first direction of the conductive wire is a conductive wire end portion drawn from the insulating portion to one side in the first direction, and is connected to one side end surface in the third direction of the substrate.

Example embodiments of the present disclosure are useful in devices having a structure in which a conductive wire drawn from a cable is connected to a substrate.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. An electronic device comprising:
a substrate extending in a first direction and a second direction intersecting the first direction; and
a cable including one end located on one side end surface in a third direction perpendicular to the first direction and the second direction of the substrate; wherein
the cable includes:
a conductive wire extending in the first direction at one end of the cable;
an insulating portion covering the conductive wire; and
an opening portion located on another end surface in the third direction of the insulating portion and opening at least to the other side in the third direction;
one side end portion in the first direction of the conductive wire is a conductive wire end portion drawn from the insulating portion to one side in the first direction, and is connected to one side end surface in the third direction of the substrate; and
at least a portion of an adhesive located on the one side end surface in the third direction of the substrate is located in the opening portion.

2. An electronic device comprising:
a substrate extending in a first direction and a second direction intersecting the first direction; and
a cable including one end located on one side end surface in a third direction perpendicular to the first direction and the second direction of the substrate; wherein
the cable includes:
a conductive wire extending in the first direction at one end of the cable;
an insulating portion covering the conductive wire; and
a bottom plate portion protruding to one side in the first direction from one side end portion in the first direction of the insulating portion at one end of the cable and stretching in the second direction; and
one side end portion in the first direction of the conductive wire is a conductive wire end portion drawn from the insulating portion to one side in the first direction, and is connected to one side end surface in the third direction of the substrate.

3. The electronic device according to claim 2, wherein
the cable further includes a protrusion plate portion protruding from an end portion in the first direction of the insulating portion to one side in the first direction at one end of the cable; and
a position of one side end portion in the first direction of the protrusion plate portion is on another side in the first direction relative to one side end portion in the first direction of the conductive wire end portion, and is different from one side end portion in the first direction of the bottom plate portion in the first direction.

4. The electronic device according to claim 2, wherein
the cable further includes an opening portion located on another end surface in the third direction of the insulating portion and opening at least to the other side in the third direction; and
at least a portion of an adhesive located on one side end surface in the third direction of the substrate is located in the opening portion.

5. The electronic device according to claim 1, wherein
the opening portion penetrates the insulating portion in the third direction;
a portion of the adhesive is located in the opening portion; and
another portion of the adhesive is located on one side in the third direction relative to one side end surface in the third direction of the insulating portion, and covers the one side end surface in the third direction of the insulating portion along at least a portion of an outer edge of the opening portion as viewed from the third direction.

6. The electronic device according to claim 5, wherein a width in the third direction of a portion covering the one side end surface in the third direction of the insulating portion of the adhesive is equal to or greater than a width in the third direction of the opening portion.

7. The electronic device according to claim 1, wherein the adhesive is located between another side end surface in the third direction of the cable and one side end surface in the third direction of the substrate in at least a portion of an outer edge in another side end portion in the third direction of the opening portion.

8. The electronic device according to claim 1, wherein
an end portion of at least in the second direction of the insulating portion is an edge portion flat in the third direction; and
the opening portion is located at the edge portion.

9. The electronic device according to claim 1, wherein the opening portion opens at an end portion in the second direction of the edge portion.

10. The electronic device according to claim 1, wherein a width in the first direction of the opening portion is equal to or greater than a width in the second direction of the conductive wire.

11. The electronic device according to claim 1, wherein a width in the second direction of the opening portion is equal to or greater than a width in the second direction of the conductive wire.

12. The electronic device according to claim 1, wherein an interval in the first direction between another side end in the first direction of the conductive wire end portion and the opening portion is equal to or greater than a width in the second direction of the conductive wire.

13. The electronic device according to claim 1, further comprising:
a fixing portion to fix the cable onto one side end surface in the third direction of the substrate; wherein
the fixing portion is located between the insulating portion and the substrate.

14. A cable comprising:
one end located on one side end surface of a substrate extending in a first direction and a second direction intersecting the first direction, the one side end surface of the substrate extending in a third direction perpendicular to the first direction and the second direction;
a conductive wire extending in the first direction at one end of the cable;
an insulating portion insulating the conductive wire; and
an opening portion located on another end surface in the third direction of the insulating portion and opening at least to the other side in the third direction; wherein
one side end portion in the first direction of the conductive wire is a conductive wire end portion drawn from the insulating portion to one side in the first direction, and is connected to one side end surface in the third direction of the substrate; and
at least a portion of an adhesive located on the one side end surface in the third direction of the substrate is located in the opening portion.

15. A cable comprising:
one end located on one side end surface of a substrate extending in a first direction and a second direction intersecting the first direction, the one side end surface of the substrate extending in a third direction perpendicular to the first direction and the second direction;
a conductive wire extending in the first direction at one end of the cable;
an insulating portion covering the conductive wire; and
a bottom plate portion protruding to one side in the first direction from one side end portion in the first direction of the insulating portion at one end of the cable and stretching in the second direction; wherein
one side end portion in the first direction of the conductive wire is a conductive wire end portion drawn from the insulating portion to one side in the first direction, and is connected to one side end surface in the third direction of the substrate.
